(19) United States
(12) Patent Application Publication
(10) Pub. No.: US 2007/0193618 A1
(43) Pub. Date: Aug. 23, 2007

(54) Integrated Solar Roofing System

(75) Inventors: Peter Bressler, Philadelphia, PA (US); Abby Nessa Feinstein, Philadelphia, PA (US); Seth Galewyrick, Philadelphia, PA (US); Martin Low, Collegeville, PA (US); Paul K. Rossi, Philadelphia, PA (US)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: SOLAR ROOFING SYSTEMS, INC., Philadelphia, PA (US)

(21) Appl. No.: 11/533,094

(22) Filed: Sep. 19, 2006

Related U.S. Application Data
(60) Provisional application No. 60/817,282, filed on Jun. 28, 2006.
(60) Provisional application No. 60/718,383, filed on Sep. 19, 2005.

(51) Int. Cl. H01L 31/042; H02N 6/00

(52) U.S. Cl. 136/244

(57) ABSTRACT

An integrated solar roofing system for installation on a roof surface and for converting solar energy into electrical energy. The system comprises a first row of photovoltaic (PV) roofing tiles having a plurality of electrically interconnected PV cells. The roofing tiles comprise a first tab that extends from the tile base and has at least one mounting hole. The first tab exposes a first electrically conductive material on the first side of the first tab. The roofing tiles further comprise a second tab located on the second side of the tile base and having at least one mounting hole extending through the second tab and tile base. The second tab exposes a second electrically conductive material on the second side of the tile base. The first tab of each roofing tile in the first row is at least partially superposed over the second tab of an adjacent roofing tile aligning the mounting holes so that the roofing tiles are in electrical series communication along the first row. The system further comprises a second row of PV roofing tiles partially overlapping the first row such that the first and second tabs of the first row are concealed.

### CROSS-REFERENCE TO RELATED APPLICATIONS

This application claims the benefit of U.S. Provisional Patent Application No. 60/718,383 filed Sep. 19, 2005 entitled “Integrated Solar Roofing System” and U.S. Provisional Patent Application No. 60/817,282 filed Jun. 28, 2006 entitled “Integrated Solar Roofing System” both of which are incorporated by reference herein their entirety.

### BACKGROUND OF THE INVENTION

This invention relates to the incorporation of photovoltaic cells into conventional type roofing tiles to create an integrated solar roofing system.

Photovoltaic (PV) cells comprising single crystal and/or thin film sub-modules are widely used to convert solar energy into electrical energy. The leading PV companies have been full spectrum solar providers developing the PV cells, designing and manufacturing the PV product, and internationally distributing their own PV products. In the past, PV companies have competed for market share strictly through technology, trying to generate more electrical power in less space. Only recently, has any attention been given to the integration of PV technology into buildings through aesthetics or usability/ease of installation of PV modules adapted for use on residential or commercial roofs. As a result, most of the available solar products are heavy, cumbersome, unavoidable conspicuous, aesthetic eyesores, and expensive wherever they are installed.

For the most part, PV companies market their products as power generators to people with the ability to generate their own energy from their residential rooftop or commercial businesses. Industry has traditionally relied on the average homeowner or business owner to seek out a self-sufficient method to create this electricity. Most solar products require a professional custom installation, increasing the costs, resistance, and aggravation of installation.

Aesthetics is generally a high priority for developers and homeowners in the market for a new roof. Conventional PV modules are generally arranged in thick raised boxes with a shinny outer surface. In addition to being conspicuous, conventional PV modules require a separate installation requiring the user to drill holes or other attachment means to the roof. Attempts have been made to include PV technology in an “integrated” manner, but they have not been successful.

A need therefore exists to provide an integrated solar roofing system that addresses the above problems in adapting PV cells to commercial and residential roofs. In this way, the solar product could install like normal pitched roof materials currently used throughout the world. The PV cell would be integrated into the currently used roofing tile or those tiles similarly used and make part of the roof. It is also desirable for the solar product to allow for sections of the roof to be designated for PV tiles or active tiles while leaving other sections to be non-PV, or inactive tiles. The non-PV tiles would have a similar appearance to the PV tiles, concealing the use of a PV system. Any area of the roof that is undesirable for PV generation would be covered with the visually consistent integrated solar roofing system inactive tiles, removing the obstacle of seamlessly blending PV cells with an existing roofing products. Together they would create a functionally and visually integrated roofing membrane. The tiles would be designed to fit current roofing material standards on size, method of installation, and building code compliance. There would be no need to drill holes in the roof nor would a professional installation service be needed, thereby dramatically reducing the installation cost while allowing the user to inconspicuously harness solar power.

### BRIEF SUMMARY OF THE INVENTION

Briefly stated, the present invention is directed to a photovoltaic (PV) roofing tile. The roofing tile comprises a tile base having a first side for facing a roof surface and a second side for facing away from the roof surface. A plurality of electrically interconnected PV cells capable of receiving solar energy are arranged on the second side of the tile base in the form of a PV circuit having first and second terminal ends. A first tab has a first side for facing a roof surface and a second side for facing away from the roof surface. The first tab extends from the tile base and has at least one mounting hole that extends through the first tab. The first tab exposes a first electrically conductive material on the first side of the first tab. The first electrically conductive material in the first tab is in electrical communication with the first terminal end of the PV circuit. A second tab is located on the second side of the tile base and has at least one mounting hole that extends through said second tab and tile base. The second tab exposes a second electrically conductive material on the second side of the tile base. The second electrically conductive material is in electrical communication with the second terminal end of the PV circuit.

In another aspect, the invention is directed to a connector for maintaining electrical contact between partially superposed PV roofing tiles in an integrated solar roofing system. The connector comprises a center disk having a central bore for receiving a fastener. A plurality of spokes extends outwardly and axially from the center disk such that the spokes have an apex spaced axially from the center disk and partially forming a body to fit within a mounting hole of a roofing tile. The spokes have a degree of flexure such that a distal end of each spoke is capable of flexing axially towards the spoke apex.

In another aspect, the invention is directed to a bus bar for connecting several series of PV roofing tiles. The bus bar comprises a connect cable and a plurality of flexible bus bar arms. The bus bar arms extended from and are in electrical communication with the connect cable. The bus bar arms are foldable back over the connect cable. A contact tab extends from a distal end of each bus bar arm. The contact tabs include an exposed electrical portion and at least one mounting hole. The exposed electrical portions are in electrical communication with the connect cable through the bus bar arms.

In another aspect, the invention is directed to an integrated solar roofing system for installation on a roof surface and for converting solar energy into electrical energy. The system comprises a first row of PV roofing tiles each having a tile base having a first side for facing the roof surface and a second side for facing away from the roof surface. The roofing tiles comprise a plurality of electrically interconnected PV cells capable of receiving solar energy and in the form of a PV circuit having first and second terminal ends. The roofing tiles further comprise a first tab having a first side for facing a roof surface and a second side for facing away from the roof surface. The first tab extends from the tile base and has at least one mounting hole that extends through the first tab. The first tab exposes a first electrically conductive material on the first side of the first tab. The first electrically conductive material on the first tab is in electrical communication with the first terminal end of the PV circuit. The roofing tiles further comprise a second tab located on the second side of the tile base and having at least one mounting hole that extends through the second tab and tile base. The second tab exposes a second electrically conductive material on the second side of the tile base. The second electrically conductive material is in electrical communication with the second terminal end of the PV circuit. The first tab of each roofing tile in the first row is at least partially superposed over the second tab of an adjacent roofing tile aligning the mounting holes so that the roofing tiles are in electrical series communication along the first row. The system further comprises a second row of PV roofing tiles partially overlapping the first row such that the first and second tabs of the first row are concealed.

### BRIEF DESCRIPTION OF THE SEVERAL VIEWS OF THE DRAWINGS

The foregoing summary, as well as the following detailed description of preferred embodiments of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a schematic front elevational view of an integrated solar roofing system in accordance with a preferred embodiment of the present invention;

FIG. 2a is a top plan view of an electrically inactive tile to be used in the integrated solar roofing system of FIG. 1;

FIG. 2b is a right side elevational view of the electrically inactive tile shown in FIG. 2a;

FIG. 3a is a top plan view of a PV roofing tile to be used in the integrated solar roofing system of FIG. 1;

FIG. 3b is a right side elevational view of the roofing tile shown in FIG. 3a;

FIG. 4a is a top perspective view of a PV roofing tile to be used in the integrated solar roofing system of FIG. 1;

FIG. 4b is a top perspective view of the roofing tile shown in FIG. 4a with a first tab partially folded upwardly to view the first side of the first tab;

FIG. 4c is an exploded cross-sectional view of a portion of the active tile taken along line 4c-4c of FIG. 3a;

FIG. 4d is an exploded cross-sectional view of a portion of the active tile taken along line 4d-4d of FIG. 3a;

FIG. 5 is a top perspective view of a connector for securing a PV roofing tile to a roof of a building;

FIG. 6 is a side elevational view of the connector shown in FIG. 5;

FIG. 7a is a top plan view of a left end bus bar in an open position;

FIG. 7b is a top plan view of a right end bus bar in an open position;

FIG. 8a is a top plan view of a left end bus bar in a folded or connected position; and

FIG. 8b is a top plan view of a right end bus bar in a folded or connected position.

### DETAILED DESCRIPTION OF THE INVENTION

Certain terminology is used in the following description for convenience only and is not limiting. The words “right,” “left,” “lower” and “upper” designate directions in the drawings to which reference is made. The words “inwardly” and “outwardly” refer to directions toward and away from, respectively, the geometric center of an integrated solar roofing system, roofing tile, connector and bus bar in accordance with the present invention, and designated parts thereof. The terminology includes the words noted above, derivatives thereof and words of similar import.

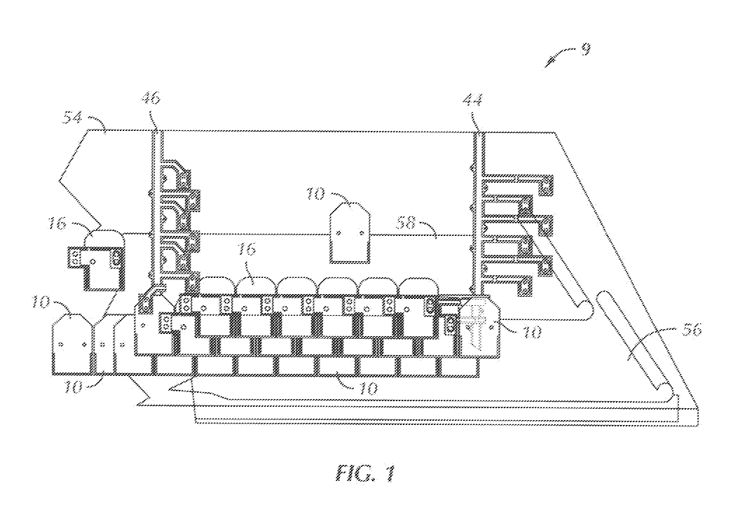

Referring to FIGS. 1-4b, there is shown an integrated solar roofing system, generally designated 9, comprised of a plurality of photovoltaic (PV) roofing tiles 16 in accordance with a preferred embodiment of the present invention that generate and transmit electricity, and electrically inactive tiles 10 that do not generate electricity, but are visually consistent with the active PV roofing tiles 16 creating a visually cohesive roof. The PV roofing tiles 16 are grouped in a section on the roof deck 54 that is a desired area for generating electricity. The area could be small involving only a few PV roofing tiles 16 or the entire roof depending on many factors including cost, location or orientation of the roof relative to the sun, obstacles such as trees or a neighboring building blocking the sun or the like. For example, most users in North America may choose to place the PV roofing tiles 16 only on the south facing side of a roof because of the extended exposure to the sun from the south due to the earth's tilt relative to the sun.

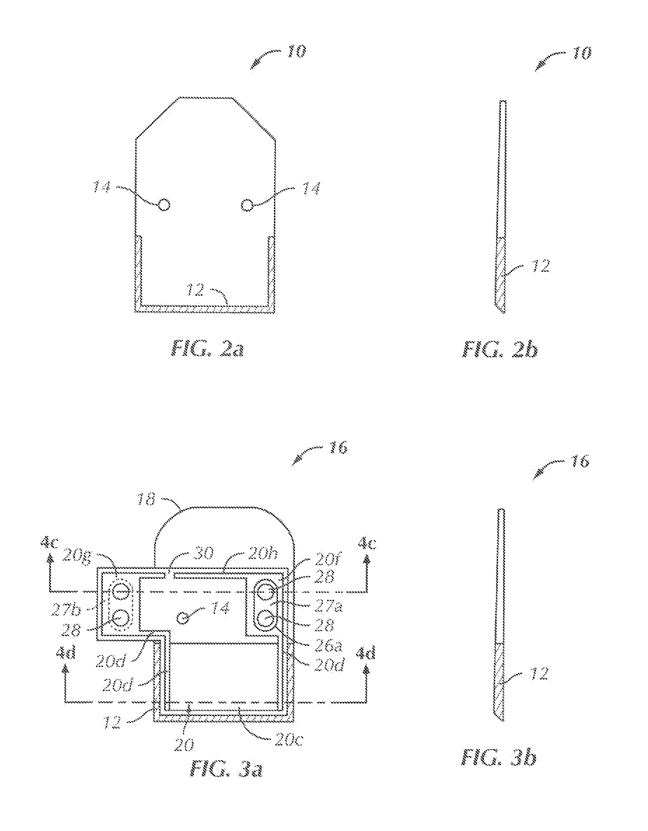

Referring to FIGS. 2a and 2b, there is shown a single inactive tile 10 comprised substantially of a preexisting roofing product or is constructed of building code approved material. The preexisting roofing product may be selected from but is not limited to the group consisting of synthetic roofing tiles (slate, cement, ceramic), authentic slate, authentic ceramic tile, authentic cement tile, metal roofing, asphalt roofing, Elastocast (BASF), Bayflex (Bayer Material Science), Zytrel and/or Hytrel (Dupont). The inactive tile 10 may also be metallic, mineral, organic, polymeric, or a nondisclosed composite material. The inactive tile 10 is generally rectangular in shape and may include at least one and preferable more than one pre-installation fastener hole 14 for securing the inactive tile 10 to the roof. The fastener holes 14 are sized to receive a nail, screw, staple, or other suitable fastener (not shown) for securing the inactive tile 10 to a roof. The area of the inactive tile 10 to be left exposed once installed is generally thicker than the rest of the inactive tile 10 and has a textured edge 12. The textured edge 12 gives the inactive tile 10 an appearance desired for aesthetic roofing purposes either from the actual or intended edge created in cutting the authentic material or a synthetic replica to make the tiles 10, 16 look authentic or otherwise visually appealing. It is understood by those skilled in the art from this disclosure that the present invention is not limited to constructing the inactive tile 10 and the PV roofing tile 16 of any particular material or shape.

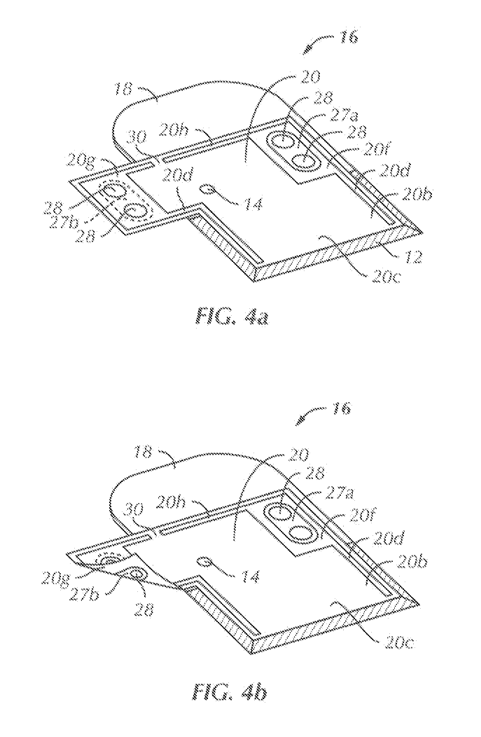

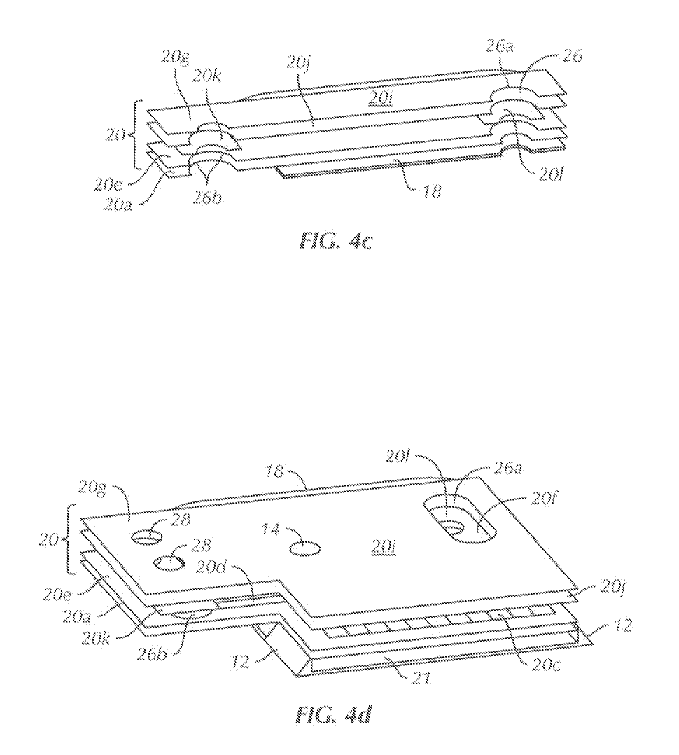

Referring to FIGS. 3a to 4b, there is shown a single PV roofing tile 16. The PV roofing tile 16 is similar in overall appearance to the inactive tile 10, particularly once installed on a roof. The PV roofing tile 16 includes a tile base 18 that is similar to the inactive tile 10. The tile base 18 has a first side for facing a roof surface 54 and a second side for facing away from the roof surface 54. The tile base 18 may include at least one and preferably more than one fastener hole 14 for securing the roofing tile to the roof 54. The PV roofing tile 16 includes a plurality of electrically interconnected PV cells 20c each capable of receiving solar energy and arranged on the first side of the tile base 18 in the form of a PV circuit 20b having first and second terminal ends. A first tab 20g extends from the tile base 18 and has a fist side for facing a roof surface and a second side for facing away from the roof surface. The first tab 20g has at least one mounting hole 28 extending through the first tab 20g. The first tab 20g exposes a first electrically conductive material 27b on the first side of the first tab 20g. The first electrically conductive material 27b is in electrical communication with the first terminal end of the PV circuit 20b. A second tab 20f is located on the second side of the tile base 18. The second tab 20f has a least one mounting hole 28 extending through the second tab 20f and the tile base 18. The second tab 20f exposes a second electrically conductive material 27a on the second side of the tile base 18. The second electrically conductive material 27a is in electrical communication with the second terminal end of the PV circuit 20b.

A flat tin copper bypass lead 20h extends between the first and second terminal ends of the PV circuit 20b. A bypass diode 30 is provided in the bypass lead 20h. The bypass diode 30 and bypass lead 20h are electrically connected between the first and second electrically conductive materials 27b, 27a of the first and second tabs 20g, 20f in parallel with the PV circuit 20b. The bypass diode 30 is positioned so that if an electrically generating portion of the PV cells 20c is not performing or is broken, any electricity being routed through that portion of the PV circuit 20b would have an alternative route of travel. That is, the bypass diode 30 allows current to flow along a row of PV roofing tiles 16 even if one or more of the PV roofing tiles 16 in a series is not working or nor properly working.

Referring now to FIGS. 4a-4d, a PV laminate 20 is located on the second side of the tile base 18. A portion of the PV laminate 20 is in an area that is the exposed area of the PV roofing tile 16 once it is installed on a roof 54, as described in more detail hereinafter. Though the PV laminate 20 is generally thin, the tile base 18 preferably includes a recess 21 to allow the top surface of the PV laminate 20 to be generally flush with the textured edge 12 of the tile base 18. The PV laminate 20 is preferably attached within the recess 21 in the tile base 18 using an integration adhesive or other means (not shown) in a separate step. Alternatively, the PV laminate 20 can be insert molded to the tile base 18 during manufacture of the PV roofing tile 16 or can be secured to the tile base 18 in some other manner known in the art.

The bottom layer of the PV laminate 20 is preferably comprised of a backsheet 20a made of PET or some other suitable insulator material. A PV circuit 20b is secured to the top of the PET backsheet 20a using a first ethyl vinyl acetate (EVA) laminate adhesive 20c. The first EVA laminate adhesive 20a does not become tacky until it is heated. Some other suitable adhesive could alternatively be used. The PV circuit 20b includes first and second terminal ends and a plurality of electrically interconnected PV cells, schematically numbered 20c. The PV laminate 20 may cover or encapsulate the PV cells 20c. The PV circuit 20b also includes flat tin copper leads 20d extending from the layer of PV cells 20c to first and second generally parallel tin copper flat tabs 20k, 20l. The first flat tab 20k located in the first tab 20g is connected to the first terminal end of the PV circuit 20b and the second flat tab 20l located in the second tab 20f is connected to the second terminal end of the PV circuit 20b. A generally flat tin copper lead 20h extends directly between a second side of the first and second flat tabs 20k, 20l. The PV circuit 20b is preferably constructed of a material selected from, but not limited to, silicon wafers, thin film silicone, copper indium gallium selenide film, cadmium telluride, or nanotechnology. The PV circuit 20b and the connected circuitry 20d, 20h, 20k, 20l, 30 are not limited to the preferred materials and may comprise any other suitable conductive material. The electric circuitry may be printed on the back side of a laminate layer containing the PV circuit 20b to conceal the PV circuit 20b from the second side of the tile base 18.

A transparent layer 20i is laminated to the top side of the PV circuit 20 and the exposed portions of the first EVA laminate adhesive 20e preferably with a second EVA laminate adhesive 20j. Some other suitable adhesive or other type of fastener may alternatively be used. The transparent layer 20i is preferably constructed from but is not limited to ETFE fluorinated polymer Tefzel, Aklar, silicone oxide or other water vapor barrier layers such as glass. The transparent layer 20i allows light to fall onto the PV cells 20c while providing a protective cover for the PV cells 20c and the PV circuit 20b. The transparent layer 20i may have a textured, antireflective, or tinted surface if desired.

The PV laminate 20 is formed by assembling all of the respective layers and placing the laminate in a vacuum laminator (not shown). However, it is understood by those skilled in the art from this disclosure that other methods could be used to assemble the PV laminate 20. For instance, the rolling co-molding process could be used without departing from the spirit and scope of the invention.

The transparent layer 20i and the second EVA laminate adhesive 20j include an aligned generally oval shaped cutout area 26a over the second tab 20f to expose the second electrically conductive material 27a on the second tab 20f. Similarly, the first EVA laminate adhesive 20e and the PET backsheet 20a include an aligned generally oval shaped cutout area 26b to exposed the first electrically conductive material 27b for being in facing engagement with the second electrically conductive material 27a of a first tab 20g of an adjacent PV roofing tile 16. This arrangement allows for contacting additional first and second tabs 20g, 20f of adjacent PV roofing tiles 16. More particularly, as depicted in FIGS. 1, 4a and 4b, the first and second electrically conductive material 27b, 27a of the PV roofing tiles 16 are positioned to superpose and align with the respective first and second electrically conductive material 27b, 27a of adjacent PV roofing tiles 16 such that the first tab 20g of a PV roofing tile 16 is in electrical communication with the second tab 20f of the next adjacent PV roofing tile 16. Thus, each row of PV roofing tiles 16 has an outermost left exposed electrically conductive material 27b associated with a first tab 20g and an outermost right exposed electrically conductive material 27a associated with a second tab 20f. The overlapping first and second tabs 20g, 20f of adjacent PV roofing tiles 16b may also include a conductive adhesive to prevent oxidation and contamination of the electrical communication therebetween. The PV roofing tile 16 is not limited to the above described first and second tabs 20g, 20f and may include any other connection configuration consistent with the sprit and scope of the present invention. For example, the first and second tabs 20g, 20f may have a mirrored configuration or may be oriented to extend from the top or bottom of the tile base 18 rather than the sides.

Each first and second tab 20g, 20f has at least one mounting hole 28, and preferably two mounting holes 28, extending through the electrically conductive material 27b and 27a. The mounting holes 28 extend entirely through the remaining layers in the tile base 18 and PV laminate 20 of the PV roofing tile 16. In alternative embodiments, the mounting holes 28 are not manufactured through every layer of the PV laminate 20 but are rather created by a nail or other securing means during installation. It is understood by those of ordinary skill in the art that the contact tabs 20f, 20g may only need one mounting hole 28. The use of two mounting holes 28 as depicted in the figures is for redundancy purposes to ensure that an electrical connection between the PV roofing tiles 16 is maintained.

When the first and second tabs 20g, 20f of adjacent PV roofing tiles 16 are interconnected, a circuit is completed connecting each PV roofing tile 16 to each adjoining PV roofing tile 16. Electricity generated by the PV circuit 20b travels through the first tab 20g into the connected second tab 20f of the adjacent PV roofing tile 16 or vice versa depending on the circuitry. The PV circuit 20b includes negative and positive electrical connection circuits (not shown) for outputting the DC voltage generated by the PV cells 20c. The negative and positive circuits are connected to the flat tin copper leads 20d so that the first tab 20g could be negative or positive and so that the second tab 20f could be negative or positive, as needed.

While a preferred series of layers for the PV laminate 20 has been described above, it is understood by those of ordinary skill in the art from this disclosure that other arrangements of layers and other materials for the individual layers could be used to achieve the same result of securing PV cells 20c to a roofing tile base 18. For instance, the second EVA laminate adhesive 20j could be omitted and a standard liquid adhesive could be used or an electrically conductive material other than tin copper could be used for the electrical leads without departing from the spirit and scope of the invention.

Referring to FIG. 1, the PV roofing tiles 16 are connected in series in between a right end bus bar 44 and a left end bus bar 46 for generating electricity. The PV roofing tiles 16, inactive tiles 10, the right bus bar 44 and left bus bar 46 are installed on top of a conventional underlayment system on top of the roof deck 54. For example, prior to the installation of any of the roof tiles 10, 16, a severe climate underlayment 56 comprising at least two layers of underlayment cemented together, or self-adhering, polymer-modified-bitumen sheets, must be installed to extend inside the exterior wall line of the building at all valleys, eaves, rigs, edges, vertical flashing, and areas where venting is to be installed. One commercially available severe climate underlayment is available from Eco-Products, Inc. of Mundelein, Ill. under the name Ecostar Glacier Guard. After the severe climate underlayment is installed, a single layer of Type 30 asphalt underlayment or similar underlayment is preferably applied over the remaining roof deck area. The application and type of underlayments are well known to those of ordinary skill in the art and, therefore, further description thereof is omitted for purposes of convenience only and is not limiting.

Beginning at an eave, one layer of inactive tiles 10 is installed with two fasteners (not shown) per tile in the fastener holes 14 that may or may not be predisposed in the inactive tile 10. This first row of inactive tiles 10 becomes the starter row. A second row of inactive tiles 10 is similarly fastened directly over the first row with no exposure of the first row and with a horizontal offset of half a tile. Subsequent tiles 10, 16 are similarly installed up the roof slope overlapping or partially superposed over the previous row but allowing for an exposure of approximately half of the previous tile, approximately six inches, and a gap in between each tile, approximately half an inch. The last inactive tile 10 in each row butts up against a hip or valley (not shown). The last inactive tile 10 can be easily cut on site to the desired width to fit the roof deck 54. The present invention is not limited to this preferred installation method and may have different underlayments, securing methods and overlap techniques and sizes.

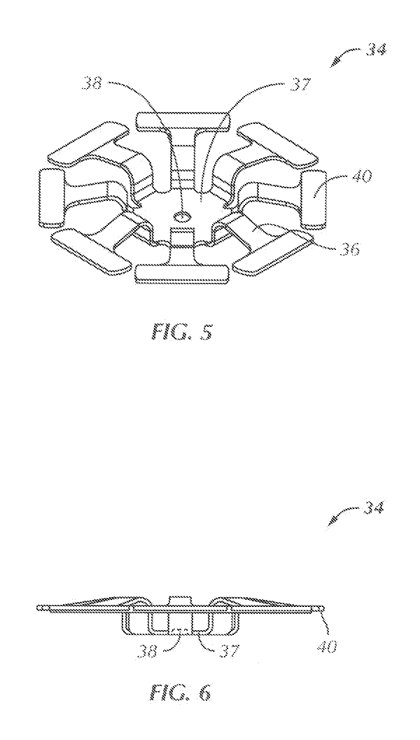

Referring now to FIGS. 5 and 6, the first and second tabs 20g, 20f of adjacent PV roofing tiles 16 are preferably held in facing electrical engagement by a connector 34. The connector 34 is comprised of a center disk 37 having a central bore 38 for receiving a fastener. A plurality of spokes 36 extend radially outwardly and axially from the center disk 37 such that the spokes 36 have an apex spaced axially from the center disk 37 and partially form a generally cylindrical body to fit within a mounting hole 28 of a PV roofing tile 16. The spokes 36 are preferably equally circumferentially spaced around the center disk 37 and have a general L-shape. The spokes 36 have a degree of flexure such that a distal end of each spoke 36 is capable of flexing axially toward the spoke apex. The spokes 36 each preferably have a least one connector tab 40 extending from the distal end thereof. The connector tabs 40 are positioned generally in the same plane and are axially spaced from and generally parallel to the center disk 37.

The connectors 34 are also used when securing adjacent PV roofing tiles 16 to the roof deck 54. A first tab 20g of an PV roofing tile 16 is placed on top of the second tab 20f of an adjacent PV roofing tile 16, placing the exposed first and second electrically conductive material 27b, 27a in facing electrical engagement. The connector 34 is placed on each mounting hole 28 of the first tab 20g. The center disk 37 and the partially formed generally cylindrical body extend through the mounting hole 28. A nail, screw or other fastener is driven through the small hole 38 in the center disk 37 of the connector 34. The center disk 37 of the connector 34 is driven toward the roof deck 54 with the nail, screw or other fastener as they extend through the mounting holes 28 of both overlapping first and second tabs 20g, 20f. The center disk 37 is positioned axially lower than the connector tabs 40. This allows for the center disk 37 to be driven through the mounting holes 28 towards the roof deck 54.

The axial distance between the center disk 37 and the connector tabs 40 is less than the thickness of the fist and second tabs 20g, 20f such that when a nail or other fastener is driven through the central bore 38, the spokes 36 flex upwardly causing the connector tabs 40 to apply pressure to the back of the first tab 20g. The pressure around the radius of the connector 34 is distributed around the circumference of the connector 34 because of the flexing of the spokes against the surface which is not even. The force from the connector 34 to the first tab 20g causes the first electrically conductive material 27a on the first tab 20g and the second electrically conductive material 27b on the second tab 20f to remain in electrical contact, thereby completing a circuit between two adjacent PV roofing tiles 16. The spokes 36 ensure that at least a portion of the first and second electrically conductive material 27b, 27a remain in electrical contact with each other even if there is a shift in the tiles due to thermal expansion, ice pressure, structural shift in the roof or damage. In a preferred embodiment, the connector 34 is formed of spring steel due to its responsive properties, but the connector may be formed of any variety of materials including synthetic material that allows continuous pressure to be exerted on the first and second tabs 20g, 20f over an extended period of time and are corrosive resistant. A sealant, such as an epoxy, (not shown) or mechanical closure, such as snap seal similar to that of a ZipLoc bag enclosure, (not shown) may be incorporated around the outer edges of the first and second tabs 20g, 20f to prevent water and debris from getting in between the superposed first and second tabs 20g, 20f and disrupting the electrical circuit or damaging the PV roofing tiles 16.

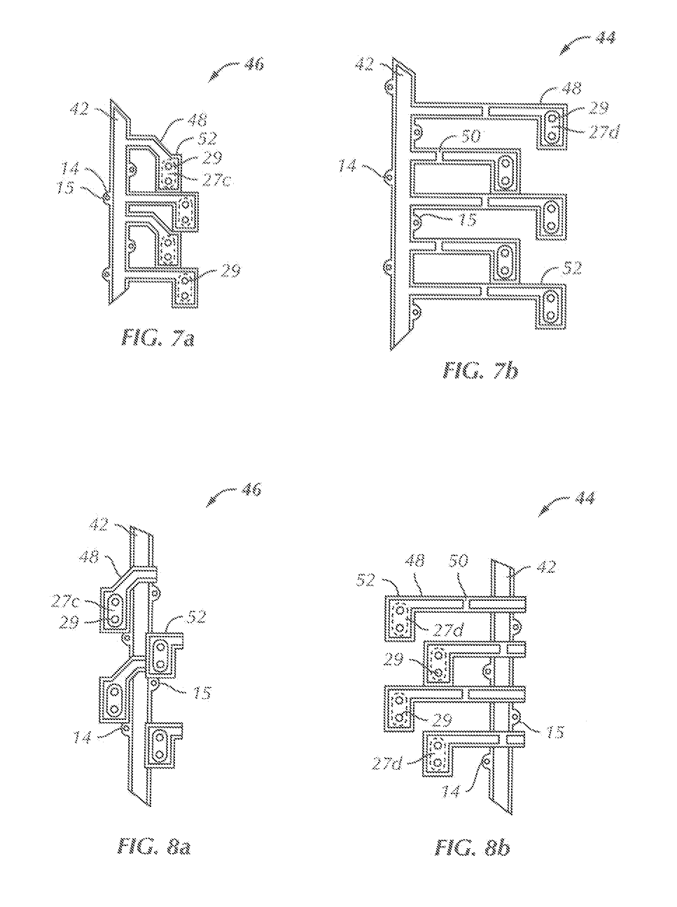

Referring now to FIGS. 1 and 7a-8b, a row of PV roofing tiles 16 is connected at each end to a left and right bus bar 46, 44. The bus bars 44, 46 function as a traditional PV combiner boxes would, combining a series of stings of PV roofing tiles 16 in parallel, and transmitting the generated electricity off of the roof. The bus bars 44, 46 are sized according to the number of rows of PV roofing tiles 16. The bus bars 44, 46 include a plurality of flexible bus bar arms 48 extending from and being in electrical communication with a connect cable 42. The connect cable 42 is positioned vertically on the roof 54 as shown in FIG. 1 and each end is connected to an electrical system (not shown) extending from its base to be configured depending on the specifics of the system 9. The bus bars 44, 46 include a series of laterally extending tabs 15 which are secured to the roof by nails, screws, or other fasteners along the length of the bus bars 44, 46. The bus bars 44, 46 are installed prior to the installation of any inactive tiles 10 or PV roofing tiles 16. The bus bars 44, 46 are installed where it is predicted that the ends of the perimeter of the section that has been predetermined to be installed with PV roofing tiles 16. A contact tab 52 extends from a distal end of each bus bar arm 48. The contact tabs 52 include an exposed electrical portions 27d, 27c and at least one mounting hole 28. The exposed electrical portions 27d, 27c are in electrical communication with the connect cable 42 through the bus bar arms 48. Similar to the PV roofing tile 16, the bus bars 44, 46 have a bypass diode 50 between the connect cable 42 and the contact tabs 52. The bypass diode 50 allows for the system 9 to continue to generate electricity if a PV roofing tile 16, or bus bars arm 48 shorts or opens by bypassing the row of PV roofing tiles 16 connected the bus bar 48. The bypass diode 50 also prevents the backflow of electricity into a row of non working or underperforming PV roofing tiles 16. The system 9 may also be configured to automatically bypass underperforming or malfunctioning rows of PV roofing tiles 16.

The bus bar arms 48 are foldable back over the connect cable 42 to allow for the connect cable 42 to be installed first and allows the position of the fold in a bus bar arm 48 to vary to adapt to the final location of the end of the row of PV tiles 16. Because of the gaps between PV roofing tiles 16 and inactive tiles 10 can vary during installation, the folding of the bus bar arms 48 allows for this variance. When folded over, the bus bar arms 48 can be adjusted to fit the length of the row of PV roofing tiles 16. The bus bar arms 48 are then covered by overlapping inactive tiles 10 or PV roofing tiles 16 in the next row vertically up the roof deck 54. The bus bars 44, 46 are completely covered once all the tiles 10, 16 are installed.

Once the inactive tiles 10 and the PV roofing tiles 16 are secured to the roof deck 54 covering the connect cable 42 of the bus bars 44, 46, the bus bar arms 48 are folded over and connected to the corresponding first and second tabs 20g, 20f of the PV roofing tile 16. A plurality of inactive tiles 10 may include an electric circuit 20b without the PV cells 20c to allow a row of PV roofing tiles 16 to be electrically extended. A connector 34 is similarly used to connect the bus bar contact tabs 52 to the first and second tabs 20g, 20f of the PV roofing tiles 16. The bus bar contact tabs 52 on the bus bars 44, 46 complete the circuit of a row of PV roofing tiles 16.

When an inactive tile 10 or PV roofing tile 16 is replaced, only the overlapping tiles need be removed and a view tile 10, 16 can be inserted. Because the synthetic tiles may be bent during replacement, tape or adhesive may be placed between the overlapping portion of the tiles 10, 16. Though usually unnecessary, the tape or adhesive may also be initially applied during installation.

The integrated solar roofing system may also omit the use of bus bars 44, 46 or have bus bars 44, 46 without bus bar arms 48. The bus bars 44, 46 may be integrated into PV roofing tiles 16 at the end of a row, attached to inactive tiles 10, connected to the PV roofing tiles 16 where the first or second tab 20g, 20f is extended, or connected by wires or other similar means. In addition, the integrated solar roofing system may have PV roofing tiles 16 that are connected in series vertically and parallel horizontally and a feedback and alert system to notify a user if a PV roofing tile 16 fails or is underperforming.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

I/we claim:

1. A photovoltaic roofing tile comprising:
a tile base having a first side for facing a roof surface and a second side for facing away from the roof surface;
a plurality of electrically interconnected photovoltaic cells capable of receiving solar energy and arranged on the second side of the tile base in the form of a photovoltaic circuit having first and second terminal ends;
a first tab having a first side for facing a roof surface and a second side for facing away from the roof surface, the first tab extending from the tile base and having at least one mounting hole extending through the first tab, the first tab exposing a first electrically conductive material on the first side of the first tab the first electrically conductive material in the first tab being in electrical communication with the first terminal end of the photovoltaic circuit; and
a second tab located on the second side of the tile base and having at least one mounting hole extending through said second tab and tile base, the second tab exposing a second electrically conductive material on the second side of the tile base, the second electrically conductive material being in electrical communication with the second terminal end of the photovoltaic circuit.

2. The roofing tile of claim 1, further including a photovoltaic laminate covering the photovoltaic cells.

3. The roofing tile of claim 2, wherein the laminate encapsulates the photovoltaic cells.

4. The roofing tile of claim 2, wherein the photovoltaic laminate includes a textured transparent layer.

5. The roofing tile of claim 1, further including a bypass diode electrically connected between the first and second electrically conductive material of the first and second tabs in parallel with the photovoltaic circuit.

6. The roofing tile of claim 1, wherein the base tile includes a fastener hole for securing the roofing tile to the roof.

7. The roofing tile of claim 1, wherein the base tile includes textured and tapered edges, the photovoltaic cells being recessed in the base tile such that the tapered edges are generally flush with the photovoltaic cells on the second side of the roofing tile.

8. A connector for maintaining electrical contact between partially superposed photovoltaic roofing tiles in an integrated solar roofing system, the connector comprising:
a center disk having a central bore for receiving a fastener; and
a plurality of spokes extending outwardly and axially from the center disk such that the spokes have an apex spaced axially from the center disk and partially forming a body to fit within a mounting hole of a roofing tile, the spokes having a degree of flexure such that a distal end of each spoke is capable of flexing axially towards the spoke apex.

9. The connector of claim 8, wherein at least one connector tab extends from the distal end of the spokes, the connector tabs being positioned generally in the same plane and axially spaced from and generally parallel to the center disk.

10. The connector of claim 8, wherein the spokes are generally L-shaped.

11. The connector of claim 8, wherein the partially formed body is generally cylindrical.

12. The connector of claim 8, wherein the connector arms are equally spaced around the center disk.

13. A bus bar for connecting several series of photovoltaic roofing tiles, the bus bar comprising:
a connect cable;
a plurality of flexible bus bar arms extending from and being in electrical communication with the connect cable, the bus bar arms being foldable back over the connect cable; and
a contact tab extending from a distal end of each bus bar arm, the contact tabs including an exposed electrical portion and at least one mounting hole, the exposed electrical portions being in electrical communication with the connect cable through the bus bar arms.

14. The bus bar of claim 13, the bus bar further comprising a plurality of tabs extending laterally along the length of the bus bar.

15. The bus bar of claim 14, wherein the tabs include a plurality of fastener holes.

16. The bus bar of claim 13, wherein the bus bar arms include a bypass diode between the connect cable and the contact tabs.

17. The bus bar of claim 13, wherein the exposed electrical connection is on a roof facing side of the contact tabs prior to folding the bus bar arms.

18. The bus bar of claim 13, wherein the exposed electrical connection is on a skyward facing side of the contact tabs prior to folding the bus bar arms.

19. An integrated solar roofing system for installation on a roof surface and for converting solar energy into electrical energy, the system comprising:
a first row of photovoltaic roofing tiles each having a tile base having a first side for facing the roof surface and a second side for facing away from the roof surface, the roofing tiles comprising:
a plurality of electrically interconnected photovoltaic cells capable of receiving solar energy and in the form of a photovoltaic circuit having first and second terminal ends;
a first tab having a first side for facing a roof surface and a second side for facing away from the roof surface, the first tab extending from the tile base and having at least one mounting hole extending through the first tab, the first tab exposing a first electrically conductive material on the first side of the first tab, the first electrically conductive material in the first tab being in electrical communication with the first terminal end of the photovoltaic circuit;
a second tab located on the second side of the tile base and having at least one mounting hole extending through the second tab and tile base, the second tab exposing a second electrically conductive material on the second side of the tile base, the second electrically conductive material being in electrical communication with the second terminal end of the photovoltaic circuit;
wherein the first tab of each roofing tile in the first row is at least partially superpose over the second tab of an adjacent roofing tile aligning the mounting holes so that the roofing tiles are in electrical series communication along the first row; and
a second row of photovoltaic roofing tiles partially overlapping the first row such that the first and second tabs of the first row are concealed.

20. The integrated solar roofing system of claim 19, the system further comprising a connector, the connector comprising:
a center disk having a central bore for receiving a fastener; and
a plurality of spokes extending outwardly and axially from the center disk such that the spokes have an apex spaced axially from the center disk and partially forming a body to fit within a mounting hole of a roofing tile, the spokes having a degree of flexure such that a distal end of each spoke is capable of flexing axially towards the spoke apex;
wherein a fastener is driven into the central bore of the connecter and into the roof deck such that the partially formed body of the connector fits within the mounting holes of the adjacent roofing tiles of the first row and the spokes apply pressure to the second side of the first tab toward the roof deck to keep the first and second electrically exposed portions of the first and second tabs of adjacent roofing tiles of the first row in electrical communication.

21. The integrated solar roofing system of claim 19, the system further inculding a third row of roofing tiles, the third row of tiles including electrically inactive tiles.

22. The integrated solar roofing system of claim 21, wherein the inactive tiles have an external appearance which is generally visually consistent with an external appearance of the photovoltaic roofing tiles.

23. The integrated solar roofing system of claim 19, wherein the first and second rows are connected in parallel at the end of each row by bus bars.

24. The integrated solar roofing system of claim 23, wherein the bus bars include a plurality of flexible bus bar arms extending from and being in electrical communication with the connect cable, the bus bar arms being foldable back over the connect cable and a contact tab extending from a distal end of each bus bar arm, the contact tabs including an exposed electrical portion and at least one mounting hole, the exposed electrical portions being in electrical communication with the connect cable through the bus bar arms.

25. The integrated solar roofing system of claim 23, wherein the bus bars further comprise a plurality of tabs extending laterally along the length of the bus bar.

26. The bus bar of claim 25, wherein the tabs include a plurality of fastener holes.

27. The bus bar of claim 23, wherein the bus bar arms include a bypass diode between the connect cable and the contact tabs.

28. The bus bar of claim 23, wherein the exposed electrical connection of one of the bus bars is on a roof facing side of the contact tabs prior to folding the bus bar arms.

29. The bus bar of claim 23, wherein the exposed electrical connection of one of the bus bars is on a skyward facing side of the contact tabs prior to folding the bus bar arms.
